(19) United States
(12) Patent Application Publication
(10) Pub. No.: US 2025/0129469 A1
(43) Pub. Date: Apr. 24, 2025

(54) METHOD FOR AREA-SELECTIVE GROWTH OF NOBLE METAL THIN FILMS USING ATOMIC LAYER DEPOSITION

(71) Applicant: KOREA INSTITUTE OF SCIENCE AND TECHNOLOGY, Seoul (KR)

(72) Inventors: Han KIM, Seoul (KR); Ji-Soo JANG, Seoul (KR); Sunghoon HUR, Seoul (KR); Hyun-Cheol SONG, Seoul (KR); Seung Hyub BAEK, Seoul (KR); Ji-Won CHOI, Seoul (KR); Jin Sang KIM, Wanju-gun (KR); Chong Yun KANG, Seoul (KR); Seong Keun KIM, Seoul (KR)

(73) Assignee: KOREA INSTITUTE OF SCIENCE AND TECHNOLOGY, Seoul (KR)

(21) Appl. No.: 18/794,977

(22) Filed: Aug. 5, 2024

(30) Foreign Application Priority Data
Oct. 19, 2023 (KR) 10-2023-0140605

(51) Int. Cl. C23C 16/04; C23C 16/06

(52) U.S. Cl. CPC C23C 16/04; C23C 16/06

(57) ABSTRACT

The present invention relates to a method for area-selective growth of a noble metal thin film using atomic layer deposition, which can increase the growth thickness of a thin film with a high selectivity by inducing the generation of volatile noble metal oxides and suppressing the growth of the thin film in non-growth areas in depositing a noble metal thin film on the growth area of a substrate using nucleation delay.

### DESCRIPTION ABOUT NATIONAL RESEARCH AND DEVELOPMENT SUPPORT

This study was supported by the technology development programs of Ministry of Science and ICT, Republic of Korea (Projects No. 1711185280 and No. 1711201879) under the Korea Institute of Science and Technology.

### CROSS-REFERENCE TO RELATED APPLICATIONS

The present application claims the benefit under 35 USC 119 (a) of Korean Patent Application No. 10-2023-0140605 filed on Oct. 19, 2023, in the Korean Intellectual Property Office, the entire disclosure of which is incorporated herein by reference for all purposes.

### BACKGROUND OF THE INVENTION

### 1. Field of the Invention

The present invention relates to a method for area-selective growth of a noble metal thin film using atomic layer deposition. More particularly, the present invention relates to a method for area-selective growth of a noble metal thin film using atomic layer deposition, which can increase the growth thickness of a thin film with a high selectivity by inducing the generation of volatile noble metal oxides and suppressing the growth of the thin film in non-growth areas in depositing a noble metal thin film on the growth area of a substrate using nucleation delay.

### 2. Description of the Related Art

Lithography is a technology that is essentially applied to thin film patterning, but edge placement error (EPE) is occurring due to device miniaturization. EPE is a problem that occurs when a mask cannot be aligned to the correct position due to the miniaturization of the device during the lithography process, and this EPE reduces the reliability and durability of the device.

Area-selective atomic layer deposition was proposed as a way to solve the EPE problem of the lithography process. Area-selective atomic layer deposition is a method of depositing a thin film only on a specific area of a substrate and does not require a separate patterning process using a mask.

Area-selective atomic layer deposition methods are classified into methods using deposition inhibitors and methods using nucleation delay. The former method has the disadvantage of requiring a process of coating a deposition inhibitor on the non-growth area of the substrate, and process complexity or low selection ratio depending on the type of deposition inhibitor. When using nucleation delay, there is an advantage of not using a deposition inhibitor, but as the deposition cycle is repeated, the thin film grows in the non-growth area (see FIG. 2), so an additional etching process is required to remove the thin film in the non-growth area.

Korean Registered U.S. Pat. No. 2,027,776 (Patent Document 1) and Korean Patent Application Publication No. 2023-0059167 (Patent Document 2) disclose an atomic layer deposition method using a deposition inhibitor, and US Registered U.S. Pat. No. 9,716,012 (Patent Document 3) and ‘Jinseon Lee et al., Inherently Area-Selective Atomic Layer Deposition of SiO2 Thin Films to Confer Oxide Versus Nitride Selectivity. Adv. Funct. Mater. 2021, 31, 2102’ (Non-Patent Document 1) disclose an atomic layer deposition method using nucleation delay.

As disclosed in Patent Document 3 and Non-Patent Document 1, when nucleation delay is used, a thin film is formed in the non-growth area as the cycle repeats. Further, in order to increase the growth thickness of the thin film with a high selectivity in the growth area, an etching process for the thin film in the non-growth area is essential.

### DOCUMENTS OF RELATED ART

(Patent Document 1) Korean Registered U.S. Pat. No. 2,027,776 (published Nov. 4, 2019).
(Patent Document 2) Korean Patent Application Publication No. 2023-0059167 (published May 3, 2023).
(Patent Document 3) US Registered U.S. Pat. No. 9,716,012 (published Jul. 25, 2017).
(Non-Patent Document 1) Jinseon Lee et al., Inherently Area-Selective Atomic Layer Deposition of SiO2 Thin Films to Confer Oxide Versus Nitride Selectivity. Adv. Funct. Mater. 2021, 31, 2102.

### SUMMARY OF THE INVENTION

The present invention has been devised to solve the above problems, and has an object to provide a method for area-selective growth of a noble metal thin film using atomic layer deposition, which can increase the growth thickness of a thin film with a high selectivity by inducing the generation of volatile noble metal oxides and suppressing the growth of the thin film in non-growth areas in depositing a noble metal thin film on the growth area of a substrate using nucleation delay.

In order to achieve the above object, a method for area-selective growth of a noble metal thin film using atomic layer deposition according to the present invention is constituted to comprise a first step of preparing a substrate having a growth area and non-growth area showing a difference in nucleation delay; a second step of supplying a noble metal precursor and adsorbing the noble metal precursor to the growth area and the non-growth area of the substrate; a third step of converting the noble metal precursor into a noble metal atomic layer by supplying an oxidizing agent; and a step of growing a noble metal thin film in the growth area by repeating a combination of the second and third steps.

In the third step, the noble metal nucleus in the growth area and the non-growth area is converted into a volatile oxide and volatilized.

A novel metal included in the novel metal precursor is a novel metal capable of generating a volatile oxide.

The noble metal is any one of iridium (Ir), ruthenium (Ru), palladium (Pd), platinum (Pt), and rhodium (Rh).

The noble metal nucleus in the non-growth area reacts with the oxidizing agent and is converted into the volatile oxide, a molar ratio of the noble metal nucleus and the oxidizing agent is controlled to generate the volatile oxide.

The molar ratio of the noble metal nucleus and the oxidizing agent is controlled through control of supply time of the oxidizing agent.

The noble metal precursor is an Ir precursor, and the oxidizing agent is O₃ or O₂ plasma.

In the third step, Ir is converted to IrO₃ and volatilized by controlling the molar ratio between Ir and O₃. The molar ratio between Ir and O₃ is controlled by controlling O₃ supply time so that O₃ molar ratio exceeds 2 in a state where the molar ratio between Ir and O₃ is 3:2, or by controlling the O₃ supply time so that the O₃ molar ratio is greater than or equal to Ir molar ratio in the molar ratio between Ir and O₃.

A unit contact area where the Ir nucleus in the non-growth area is in contact with O₃ is relatively larger than the unit contact area where an Ir thin film in the growth area is in contact with O₃, so that generation of IrO₃ in the non-growth area is promoted.

The growth area is an Al₂O₃ area, and the non-growth area is a SiO₂ area.

The method for area-selective growth of noble metal thin films using atomic layer deposition according to the present invention has the following effects.

In the process of growing a noble metal thin film in the growth area of the substrate, the noble metal nuclei in the non-growth area react with an oxidizing agent and are converted into volatile oxides and volatilized, so that the noble metal thin film can be grown with a high selectivity. In addition, since the noble metal nuclei in the non-growth area are continuously annihilated in the process of growing the noble metal thin film in the growth area, theoretically, the thickness of the noble metal thin film in the growth area can be selectively increased as needed.

In addition, unlike the conventional area-selective atomic layer deposition method using nucleation delay, an etching process to remove the thin film in the non-growth area is not required.

### BRIEF DESCRIPTION OF THE DRAWINGS

FIG. 1 is a flowchart illustrating a method for area-selective growth of a noble metal thin film using atomic layer deposition according to an embodiment of the present invention.

FIG. 2 is a reference diagram for explaining an area-selective atomic layer deposition method using nucleation delay.

FIG. 3 is a reference diagram for explaining the growth behavior of a noble metal thin film.

FIG. 4 is a reference diagram for explaining a unit contact area of Ir with O₃ in a growth area and non-growth area.

FIG. 5 shows the results of an experiment measuring a thickness of an Ir thin film in an Al₂O₃ area and SiO₂ area according to a deposition cycle.

FIG. 6 shows SEM image of each of an Al₂O₃ area and SiO₂ area at the completion of 150, 200, 250, 300, and 425 deposition cycles.

FIG. 7 shows the GIXRD analysis results of a thin film deposited according to a deposition temperature and O3 supply time in Experimental Example 2.

FIG. 8 shows an experimental result according to Experimental Example 2, showing a change in Ir deposition amount according to O₃ supply time under a deposition temperature of 250° C.

FIG. 9 shows an SEM image of an Ir thin film deposited by performing 500 and 700 deposition cycles using a deposition temperature of 250° C. and an O₃ supply time of 30 seconds.

FIG. 10 shows an experimental result showing an amount of Ir deposition according to a deposition cycle when a deposition temperature of 250° C. and an O₃ supply time of 30 seconds are applied.

FIGS. 11A and 11B show SEM and EDS analysis results according to Experimental Example 4.

### DETAILED DESCRIPTION OF THE INVENTION

The present invention proposes a technology that may grow noble metal thin films in a growth area with a high selectivity while not requiring an etching process to remove the thin film grown in a non-growth area, by suppressing the growth of the thin film in the non-growth area when growing the noble metal thin films through an area-selective atomic layer deposition method using nucleation delay.

As previously described in ‘Description of the Related Art’, when a thin film is selectively deposited on the growth area of the substrate using nucleation delay, the thin film is also deposited on the non-growth area as the cycle of the deposition process is repeated. To solve this problem, an etching process is generally applied to remove the thin film in the non-growth area (see Patent Document 3 and Non-Patent Document 1). In this way, if a separate etching process is applied to remove the thin film in the non-growth area, the effect of process simplification, which is an advantage of the area-selective atomic layer deposition method, is diluted. Further, in order to achieve a high selectivity, the etching process must be repeated, so there is a limit to increasing the growth thickness of the thin film.

The present invention focuses on the characteristic that noble metals are converted into volatile oxides under specific conditions, and proposes a technology that can grow novel metal thin film with a high selectivity in the growth area without a separate etching process by continuously converting the noble metal nuclei deposited in the non-growth area into volatile oxides, and suppressing the growth of novel metal thin films in the non-growth area. In addition, through this method, the growth thickness of the noble metal thin film may be dramatically increased compared to the conventional art.

When depositing a noble metal thin film using the atomic layer deposition method, the noble metal precursor adsorbed on the substrate is converted to a noble metal by removing its ligand through a reaction with an oxidizing agent such as O₃ or O₂ plasma, and thus, the novel metal thin film grows by repeating the process. For example, the Ir precursor is converted to Ir by reaction with O₃ to grow an Ir thin film. When the Ir precursor reacts with O₃, IrO₂ or IrO₃ may be generated in addition to Ir depending on the amount of O₃ supplied.

IrO₂ and IrO₃ are reactants generated by excessive supply of O₃. IrO₂ is a solid substance and IrO₃ is a volatile oxide and a gaseous substance. Therefore, IrO₂ is deposited on the substrate, whereas IrO₃ is volatilized upon its formation and is not deposited on the substrate. Based on these reaction characteristics, if it is possible to convert Ir deposited in the non-growth area of the substrate into IrO₃, the growth of the Ir thin film in the non-growth area may be minimized.

Since IrO₂ and IrO₃ are reactants generated by excessive supply of O₃ after the formation of Ir, the generation of IrO₂ or IrO₃ may be induced by controlling the amount of O₃ supplied. For example, the generation of IrO₂ or IrO₃ may be induced by controlling the molar ratio of Ir and O₃.

Referring to Reaction Schemes 1 to 3 below, in case that the molar ratio of Ir and O₃ is 3:2, IrO₂ is generated (Rection Scheme 1), and in case that the molar ratio of Ir and O₃ is 1:1, IrO₃ is generated (Reaction Scheme 2). In addition, IrO₃ is generated even in case that the molar ratio of IrO₂ and O₃ is 3:1 (Reaction Scheme 3).

Therefore, in a state where the molar ratio between Ir and O₃ is 3:2, if the O₃ molar ratio exceeds 2, IrO₃ is generated, and if the O₃ molar ratio is greater than or equal to the Ir molar ratio in the molar ratio between Ir and O₃, it can be seen that the reaction for IrO₃ generation occurs predominantly. In this way, the growth of the Ir thin film in the non-growth area may be suppressed by controlling the molar ratio between Ir and O₃.

2O₃→3O₂

3Ir(s)+₃O₂→3IrO₂(s) (Reaction Scheme 1)

2O₃→3O₂

2Ir(s)+₃O₂→2IrO₃(g) (Reaction Scheme 2)

2O₃→3O₂

6IrO₂(s)+3O₂→6IrO₃(g) (Reaction Scheme 3)

In addition to controlling the molar ratio between Ir and O₃ described above, Ir nuclei growth behavior in the non-growth area accelerates the conversion of Ir to IrO₃, which is explained as follows.

As IrO₃ is generated by the molar ratio between Ir and O₃, the larger the contact area between Ir nuclei and O₃, the more IrO₃ generation is promoted. In other words, the larger the unit contact area of Ir in contact with O₃, the greater the IrO₃ generation efficiency.

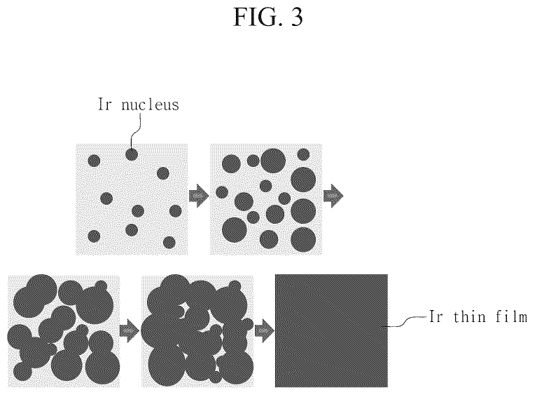

Considering the growth behavior of the Ir thin film, Ir nuclei are generated in the form of islands on the substrate, and through repetition of the deposition cycle, the size of the Ir nuclei increases and the Ir nuclei merges with neighboring Ir nuclei, and through the continuous deposition process, Ir thin film are formed (see FIG. 3).

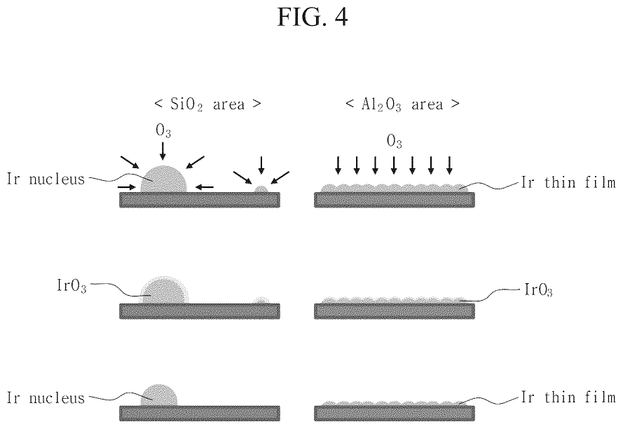

This growth behavior of the Ir thin film applies equally to both the growth area and the non-growth area, but the growth behavior of the Ir thin film in the non-growth area is expressed late due to the nucleation delay between the growth area and the non-growth area. That is, in a state where the Ir thin film with a predetermined thickness is grown in the growth area, Ir nuclei begin to be generated in the non-growth area as the deposition cycle is repeated (see FIG. 4).

In this way, at the same deposition time, the Ir thin film with densely packed Ir nuclei is formed in the growth area, while in the non-growth area, the Ir nuclei exist in the form of an island. Therefore, when O₃ is supplied, a unit contact area where the Ir nucleus in the non-growth area is in contact with O₃ is much larger than a unit contact area where the Ir thin film in the growth area is in contact with O₃ (see FIG. 4).

Therefore, as described above, the larger the unit contact area of Ir in contact with O₃, the greater the IrO₃ generation efficiency. While the Ir nuclei initially produced in the non-growth area react with O₃ and are easily converted to IrO₃, the Ir thin film in the growth area has a relatively small unit contact area with O₃, resulting in a low conversion rate of Ir to IrO₃.

Based on this principle, in converting Ir in the non-growth area into IrO₃ by controlling the molar ratio between Ir and O₃, the conversion of the Ir thin film in the growth area to IrO₃ is minimized and at the same time, the conversion of the Ir in the non-growth area to IrO₃ can be accelerated.

Hereinafter, a method for area-selective growth of a noble metal thin film using atomic layer deposition according to an embodiment of the present invention will be described in detail with reference to the drawings.

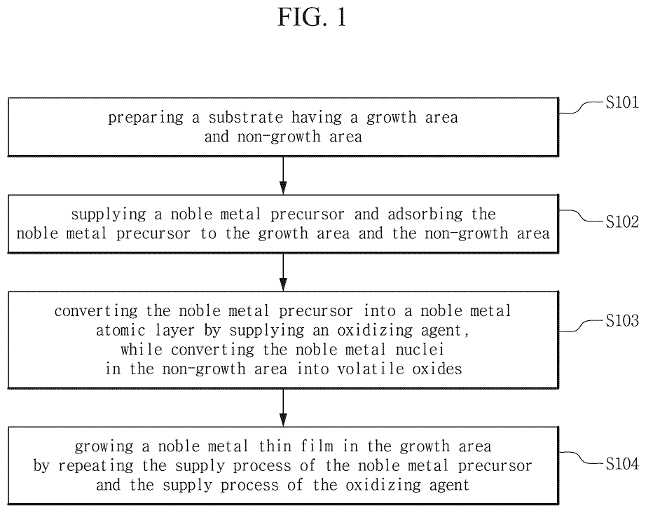

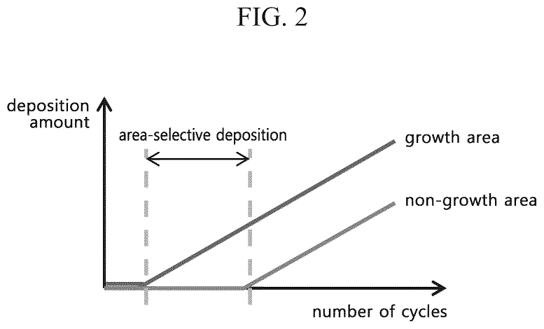

Referring to FIG. 1, first a substrate is prepared (S101). The substrate includes a growth area and a non-growth area. The growth area refers to an area where a noble metal thin film is grown, and the non-growth area refers to an area set to prevent the noble metal thin film from growing.

The growth area and non-growth area are distinguished by the characteristic of delayed generation of noble metal nuclei. In other words, in the process of repeating the atomic layer deposition cycle, the non-growth area exhibits the characteristic of generating noble metal nuclei relatively late compared to the growth area. Nucleation delay may be provided by varying the constituent materials of the substrate. In one embodiment, the substrate in the growth area may be made of aluminum oxide (Al₂O₃), and the substrate in the non-growth area may be made of silicon oxide (SiO₂) to provide nucleation delay characteristics. Referring to Experimental Example described later, Ir nuclei are generated in the growth area, Al₂O₃, after 120 deposition cycles are repeated, while Ir nuclei are generated in the non-growth area, SiO₂, after 240 deposition cycles are repeated.

In a state where the substrate divided into the growth area and non-growth area is mounted on the reaction chamber of an atomic layer deposition apparatus, a noble metal precursor supply process (S102) and an oxidant supply process (S103) are repeated to form a precious metal thin film in the growth area of the substrate (S104).

The noble metal precursor supply process includes supplying the noble metal precursor into the reaction chamber for a predetermined period of time, adsorbing the noble metal precursor on the growth area of the substrate, and purging the non-adsorbed noble metal precursor using an inert gas. The noble metal precursor is a material containing a noble metal and a ligand, and the noble metal is a material that may generate volatile oxides and may refer to any one of iridium (Ir), ruthenium (Ru), palladium (Pd), platinum (Pt), and rhodium (Rh). Also, in the case of the noble metal precursor containing Ir and a ligand, tricarbonyl (1,2,3-η)-1,2,3-tri(tert-butyl)-cyclopropenyl iridium (TICP) may be used as an example.

The oxidizing agent supply process is a process of supplying an oxidizing agent to the reaction chamber in a state where the noble metal precursor is adsorbed on the growth area of the substrate. The reaction between the noble metal precursor and the oxidizing agent removes the ligand of the noble metal precursor to form a noble metal atomic layer. O₃ or O₂ plasma may be used as the oxidizing agent to convert the noble metal precursors into noble metals. In addition, the oxidizing agent supply process includes the process of purging reaction by-products such as ligands and unreacted oxidizing agent by injecting an inert gas after the noble metal atomic layer is formed by supplying the oxidizing agent.

The combination of the noble metal precursor supply process and oxidizing agent supply process corresponds to one deposition cycle, and by repeating a plurality of deposition cycles, the thickness of the noble metal thin film may be increased by repeatedly stacking the noble metal atomic layers on the growth area of the substrate.

However, as described above, the growth area and non-growth area are distinguished by nucleation delay characteristics, and when the deposition cycle reaches a predetermined number of times, noble metal nuclei are generated not only in the growth area but also in the non-growth area, and when additional deposition cycles are repeatedly performed, the novel metal thin film is formed. Here, it is mentioned again in Patent Document 3 and Non-Patent Document 1, that an etching process is applied to remove the thin film in the non-growth area in order to minimize the growth of the thin film in the non-growth area while continuously growing the thin film in the growth area.

The present invention suppresses growth of novel metal nuclei into the noble metal thin film by continuously annihilating the noble metal nuclei at the initial stage of the growth behavior of the noble metal thin film when the non-growth area reaches the nucleation growth deposition cycle, and this is achieved through the above-described process. Specifically, by controlling the supply amount of the oxidizing agent during the oxidizing agent supply process, the noble metal nuclei generated in the non-growth area may be continuously annihilated.

In a more specific embodiment, by controlling the molar ratio between the noble metal precursor and the oxidizing agent, the growth of the noble metal thin film can be suppressed by continuously annihilating the noble metal nuclei generated in the non-growth area.

The noble metal nuclei may be continuously annihilated by the conversion of the noble metal nuclei into volatile oxides. In other words, the noble metal nuclei generated in the non-growth area may be continuously annihilated by converting them into volatile oxides, which are gaseous substances.

The control of the molar ratio between the noble metal precursor and the oxidizing agent is explained using specific embodiments as an example. In case that an Ir precursor and O₃ are used as the noble metal precursor and oxidizing agent, respectively, Ir nuclei are generated by the reaction between the Ir precursor and O₃, and when O₃ is supplied in excess, IrO₂ and IrO₃ are generated by the reaction between Ir and O₃. IrO₂ is a solid material, and is deposited on the substrate, whereas IrO₃ is a gaseous material, and volatilizes upon generation and is not deposited on the substrate.

As previously explained with respect to Reaction Schemes 1 and 2, in case that the molar ratio of Ir and O₃ is 3:2, IrO₂ is generated (see Reaction Scheme 1), and in case that the molar ratio of Ir and O₃ is 1:1, IrO₃ is generated (see Reaction Scheme 2). Based on these Reaction Schemes 1 and 2, by controlling the molar ratio between Ir and O₃, the generation of IrO₃, a volatile oxide, may be promoted and the Ir nuclei generated in the non-growth area may be continuously annihilated. Here, controlling the molar ratio between Ir and O₃ may be implemented by controlling the supply time of the oxidizing agent in the oxidizing agent supply process.

Through the principle described above, the growth of the noble metal thin film in the non-growth area may be suppressed by continuously converting the noble metal nuclei generated in the non-growth area into volatile oxide, and the principle of the present invention does not require the etching process like in Patent Document 3 or Non-Patent Document 1. In addition, as the deposition cycle is repeated, the annihilation of the noble metal nuclei in the non-growth area occurs in parallel during the repetitive deposition cycle, the thickness of the noble metal thin film in the growth area may theoretically be selectively increased as needed. For reference, in the case of Non-Patent Document 1, SiO₂ with a thickness of about 4 nm is grown when only the nucleation delay characteristic is used without an etching process, and when an etching process is applied, the experimental result is presented that the thickness increases to 10 nm. On the contrary, in the case of the present invention, as described in Experimental Example described later, the Ir thin film with a thickness of about 20.4 nm may be grown without applying an etching process.

As described above, a method for area-selective growth of a noble metal thin film using atomic layer deposition according to an embodiment of the present invention has been described. Hereinafter, the present invention will be described in more detail through Experimental Examples.

### Experimental Example 1: Nucleation Delay Characteristics

In a state where a substrate divided into an Al₂O₃ area and SiO₂ area is mounted in an atomic layer deposition chamber, at the condition of 250° C., tricarbonyl (1,2,3-η)-1,2,3-tri(tert-butyl)-cyclopropenyl iridium (TICP) gas was supplied for 8 seconds, and then Ar gas was purged for 20 seconds. Then, O₃ was supplied for 5 seconds and Ar gas was purged for 15 seconds. The above deposition cycle was repeated 500 times.

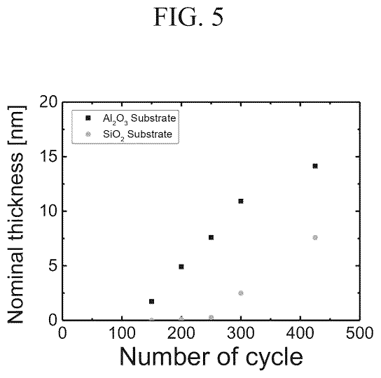

As a result of measuring the thickness of the Ir thin film in the Al₂O₃ area and SiO₂ area according to the deposition cycle (see FIG. 5), the nucleation delay in the Al₂O₃ area was found to be about 120 times, and the nucleation delay in the SiO₂ area was found to be about 240 times. The deposition amount per deposition cycle (GPC) was measured to be constant at about 0.6 Å.

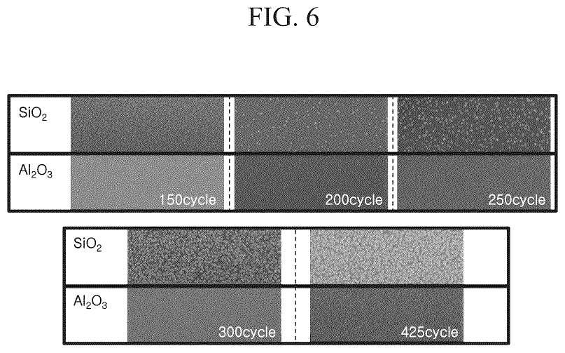

In addition, as a result of SEM analysis of each of the Al₂O₃ area and SiO₂ area at the completion of 150, 200, 250, 300, and 425 deposition cycles in the above experiment (see FIG. 6), it was observed that while a smooth and continuous Ir thin film was formed in the Al₂O₃ area at 150 deposition cycles, small-sized Ir nuclei were formed at a long distance in the SiO₂ area. It can be confirmed that as the deposition cycle increases, the Ir thin film grows even in the SiO₂ area, which is a non-growth area.

### Experimental Example 2: Phase Change Characteristics of a Thin Film According to Deposition Temperature and O₃ Supply Time

The atomic layer deposition was performed using the process conditions of Experimental Example 1, but varying the deposition temperature and O₃ supply time. The deposition temperatures were 180, 200, and 250° C., and the O₃ supply time was varied to 3, 5, 10, 30, and 60 seconds for each deposition temperature. In addition, 500 deposition cycles were performed each.

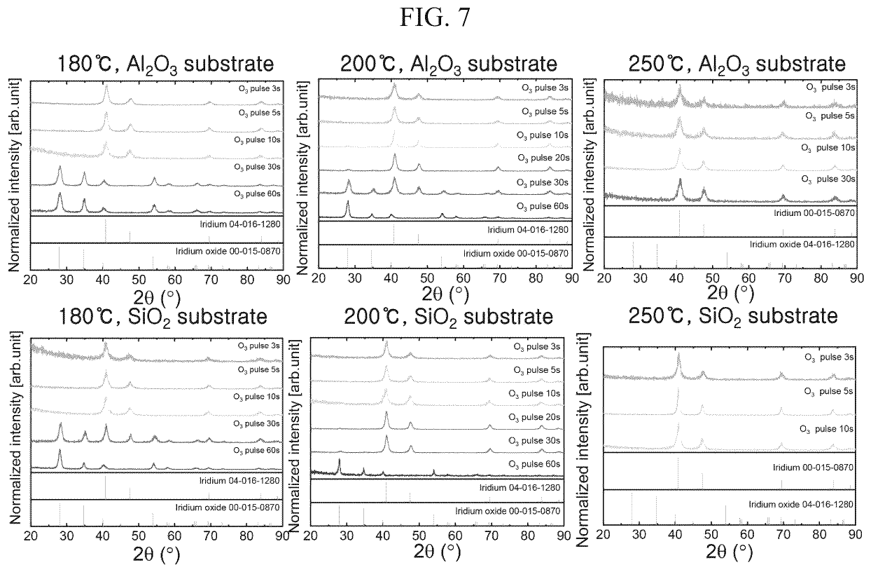

FIG. 7 shows the GIXRD analysis results of the thin film deposited according to the deposition temperature and O₃ supply time in Experimental Example 2, and Tables 1 and 2 below summarize the results of FIG. 7 and show the phase change data of the thin film according to process conditions. The peaks at the bottom of each GIXRD analysis result in FIG. 7 are peaks for Ir and IrO₂.

TABLE 1
<Phase change of a thin film according to deposition
temperature and O₃ supply time in Al₂O₃ area>

| | | O₃ supply time | | | | |
|---|---|---|---|---|---|---|
| Al₂O₃ | | O₃ 3 s | O₃ 5 s | O₃ 10 s | O₃ 30 s | O₃ 60 s |
| Deposition | 180° C. | Ir | Ir | Ir | IrO₂ | IrO₂ |
| temperature | 200° C. | Ir | Ir | Ir | Ir/IrO₂ | IrO₂ |
| | 250° C. | Ir | Ir | Ir | Ir | — |

TABLE 2
<Phase change of a thin film according to deposition
temperature and O₃ supply time in SiO₂ area>

| | | O₃ supply time | | | | |
|---|---|---|---|---|---|---|
| SiO₂ | | O₃ 3 s | O₃ 5 s | O₃ 10 s | O₃ 30 s | O₃ 60 s |
| Deposition | 180° C. | Ir | Ir | Ir | Ir/IrO₂ | IrO₂ |
| temperature | 200° C. | Ir | Ir | Ir | Ir | IrO₂ |
| | 250° C. | Ir | Ir | Ir | — | — |

Referring to FIG. 7, Table 1, and Table 2, in case that the deposition temperatures of 180° C. and 200° C. are applied, it can be confirmed that as the O₃ supply time becomes to 30 seconds or longer, the IrO₂ phase tends to be formed in both the Al₂O₃ area and the SiO₂ area. In addition, it can be seen that under the conditions of the same O₃ supply time, the IrO₂ phase is formed relatively well in the Al₂O₃ area. In addition, it can be confirmed that under the conditions of the same O₃ supply time, a pure Ir phase is generated as the deposition temperature increases.

It can be confirmed that under the deposition temperature condition of 250° C., the IrO₂ phase is not generated and only the Ir phase is generated, regardless of the substrate area and O₃ supply time. However, in case that the O₃ supply time is 60 seconds, neither the Ir phase nor the IrO₂ phase appears in the Al₂O₃ area, and in case that the O₃ supply time is 30 seconds or greater, neither the Ir phase nor the IrO₂ phase appears in the SiO₂ area. In this case, as the O₃ supply time lengthens, it is determined that the Ir phase is converted to IrO₃, a volatile oxide, and volatilized.

The phenomenon of Ir phase being converted to IrO₃ and volatilized by increasing O₃ supply time at a deposition temperature of 250° C. is also proven through changes in the amount of Ir deposition.

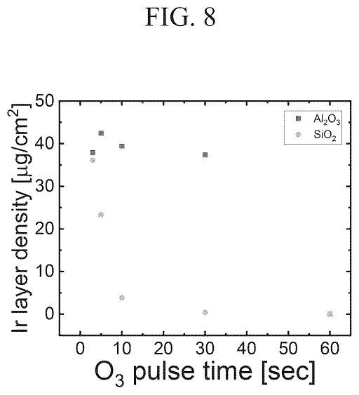

FIG. 8 shows an experimental result according to Experimental Example 2, showing the change in Ir deposition amount according to O₃ supply time under the conditions of a deposition temperature of 250° C. Referring to FIG. 8, it can be seen that the Ir deposition amounts in both the Al₂O₃ area and the SiO₂ area show the maximum amount under the condition of O₃ supply time of 3 to 5 seconds. Also, it can be seen that as the O₃ supply time becomes longer, the Ir deposition amount decreases, so in case that the O₃ supply time is 60 seconds, there is almost no amount of Ir deposition.

From these results, the supply amount of Ir precursor, that is, the supply amount of TICP, is the same regardless of the O₃ supply time. Therefore, the maximum amount of Ir deposited at a short O₃ supply time of 3 to 5 seconds decreases as the O₃ supply time becomes longer. Therefore, the decrease in Ir deposition amount means that the Ir phase changed into the IrO₃ phase and was volatilized.

Furthermore, from the results of FIG. 8, it can be confirmed that the decrease in Ir deposition amount according to O₃ supply time appears differently in the Al₂O₃ area and the SiO₂ area. In the SiO₂ area, the decrease in Ir deposition amount according to the O₃ supply time appears rapidly, and the Ir deposition amount converges to 0 after 10 seconds. On the contrary, in the Al₂O₃ area, the decrease in Ir deposition amount appears slowly, and the Ir deposition amount converges to 0 at 60 seconds.

In particular, under the condition that the O₃ supply time is 30 seconds, the Ir deposition amount is hardly reduced in the Al₂O₃ area, while the Ir deposition amount converges to 0 in the SiO₂ area, which can be said to be a result that is most consistent with the method for area-selective growth of a noble metal thin film according to the present invention. In addition, these results are experimental results that support the continuous annihilation of Ir nuclei generated in the SiO₂ area due to the difference in nucleation delay between the Al₂O₃ area and the SiO₂ area.

In the above, as an implementation principle of a method for area-selective growth of a noble metal thin film according to the present invention, the control of the molar ratio between Ir and O₃ and difference in the unit contact areas of Ir (Ir thin film vs. Ir nucleus) generated in each of the growth area (Al₂O₃) and the non-growth area (SiO₂) for O₃ have been described. That is, under conditions in which the molar ratio between Ir and O₃ is controlled (control of O₃ supply time), the Ir thin film is formed in the Al₂O₃ area due to the difference in nucleation delay, while Ir nuclei grow in the form of an island in the SiO₂ area. Therefore, the unit contact area of the Ir nuclei generated in the SiO₂ area for O₃ is relatively large compared to the Ir thin film in the Al₂O₃ area, so the conversion of the Ir thin film to IrO₃ in the Al₂O₃ area is minimized, and at the same time, the conversion of Ir nuclei to IrO₃ in the SiO₂ area is promoted (see FIG. 4).

In this way, area-selective growth of the Ir thin film may be realized by activating the growth of the Ir thin film in the Al₂O₃ area and continuously annihilating the Ir nuclei in the SiO₂ area through the conditions of deposition temperature of 250° C. and O₃ supply time of 30 seconds. Since continuous annihilation of Ir nuclei means the conversion of Ir nuclei into IrO₃, setting process conditions that enable the generation of IrO₃ is most important. As described above for the conditions for generating IrO₃, the molar ratio between Ir and O₃ was presented. However, since the generation of IrO₃ is influenced not only by the deposition temperature but also by the deposition pressure, the conversion of Ir nuclei into IrO₃ may be achieved by controlling the deposition temperature and deposition pressure.

### Experimental Example 3: Maximum Thickness and Deposition Amount of Thin Film According to Application of Optimal Process Conditions

An Ir thin film was deposited by applying 500 and 700 deposition cycles using the optimal process conditions, a deposition temperature of 250° C. and an O₃ supply time of 30 seconds, which were proven in Experimental Example 2

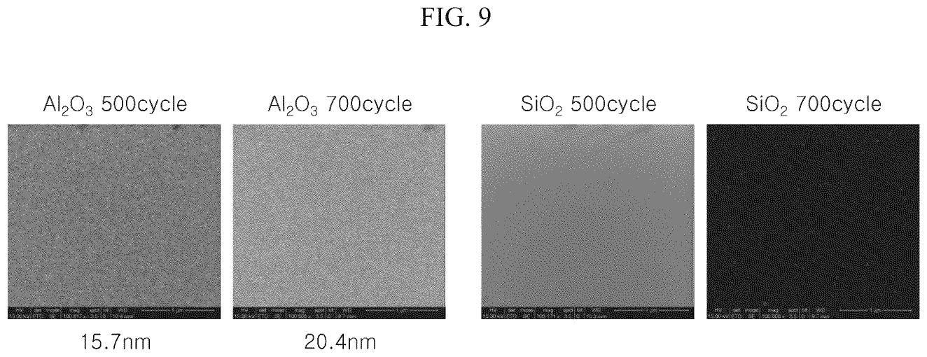

As a result, as shown in FIG. 9, in an experiment conducted with 500 deposition cycles, when the Ir thin film of 15.7 nm was deposited on the Al₂O₃ area, no growth of the Ir thin film was observed in the SiO₂ area. In addition, in an experiment conducted with 700 deposition cycles, when the Ir thin film of 20.4 nm was deposited on the Al₂O₃ area, only a trace amount of Ir nuclei were observed in the SiO₂ area and the Ir thin film was not grown.

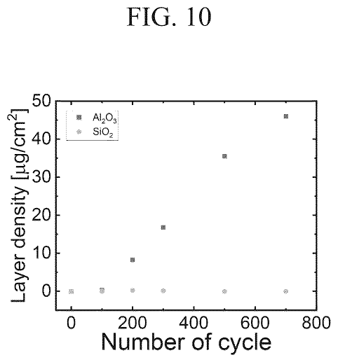

When viewed from the Ir deposition amount results (see FIG. 10), in an experiment conducted with 700 deposition cycles, about 46.0 μg/cm² of Ir was deposited in the Al₂O₃ area, while the Ir deposition amount in the SiO₂ area was less than or equal to 0.1 μg/cm². For reference, the Ir deposition amount of about 46.0 μg/cm² in the Al₂O₃ area means a thickness of about 20.4 nm when converted to theoretical density.

### Experimental Example 4: Application of Area Selective Deposition

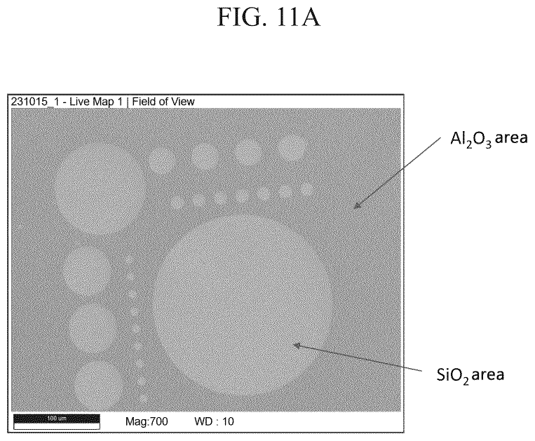

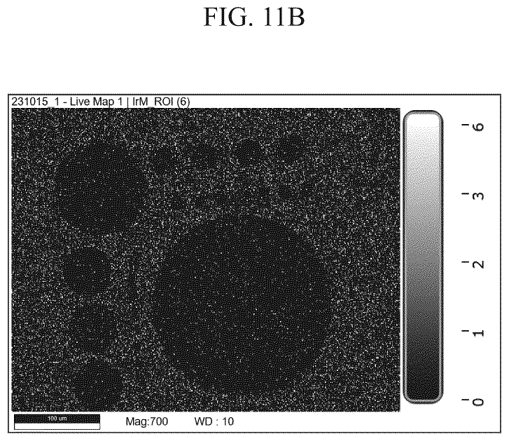

In order to confirm that various types of area-selective deposition may be performed, the growth area (Al₂O₃) and non-growth area (SiO₂) were defined as specific shapes, and the method for area-selective growth of a noble metal thin film using atomic layer deposition of the present invention was performed. Then, the results were analyzed by SEM and EDS. In detail, as shown in FIG. 11A, a substrate in which circular shapes of various sizes were divided into the non-growth area (SiO₂) and the other areas were defined as the growth area (Al₂O₃) was prepared, and the atomic layer deposition was performed by applying the process conditions of Experimental Example 1 (deposition temperature of 250° C., O₃ supply time of 40 seconds, and deposition cycle of 500 times). FIG. 11A is an SEM image after atomic layer deposition, and FIG. 11B is a SEM-EDS analysis result.

Referring to the SEM image in FIG. 11A, it can be confirmed that the Ir thin film with a smooth and continuous surface was deposited in the Al₂O₃ area while no Ir thin film was deposited in the SiO₂ area. In addition, when viewing the SEM-EDS analysis results in FIG. 11B, it can be confirmed that the Ir elements are distributed in a very uniform form in the Al₂O₃ area, and the Ir peak intensity at the noise level is observed in the SiO₂ area. Through these results, it can be confirmed that the area-selective deposition of the Ir thin film is carried out precisely.

What is claimed is:

1. A method for area-selective growth of a noble metal thin film using atomic layer deposition, comprising:
a first step of preparing a substrate having a growth area and non-growth area showing a difference in nucleation delay;
a second step of supplying a noble metal precursor and adsorbing the noble metal precursor to the growth area and the non-growth area of the substrate;
a third step of converting the noble metal precursor into a noble metal atomic layer by supplying an oxidizing agent; and
a step of growing a noble metal thin film in the growth area by repeating a combination of the second and third steps.

2. The method of claim 1, wherein in the third step, the noble metal nucleus in the non-growth area is converted into a volatile oxide and volatilized.

3. The method of claim 1, wherein a novel metal included in the novel metal precursor is a novel metal capable of generating a volatile oxide.

4. The method of claim 3, wherein the noble metal is any one of iridium (Ir), ruthenium (Ru), palladium (Pd), platinum (Pt), and rhodium (Rh).

5. The method of claim 2, wherein the noble metal nucleus in the non-growth area reacts with the oxidizing agent and is converted into the volatile oxide,
a molar ratio of the noble metal nucleus and the oxidizing agent is controlled to generate the volatile oxide.

6. The method of claim 5, wherein the molar ratio of the noble metal nucleus and the oxidizing agent is controlled through control of supply time of the oxidizing agent.

7. The method of claim 1, wherein the noble metal precursor is an Ir precursor, and the oxidizing agent is O₃ or O₂ plasma.

8. The method of claim 7, wherein in the third step, Ir is converted to IrO₃ and volatilized by controlling the molar ratio between Ir and O₃,
wherein the molar ratio between Ir and O₃ is controlled by controlling O₃ supply time so that O₃ molar ratio exceeds 2 in a state where the molar ratio between Ir and O₃ is 3:2, or by controlling the O₃ supply time so that the O₃ molar ratio is greater than or equal to Ir molar ratio in the molar ratio between Ir and O₃.

9. The method of claim 8, wherein a unit contact area where the Ir nucleus in the non-growth area is in contact with O₃ is relatively larger than the unit contact area where an Ir thin film in the growth area is in contact with O₃, so that generation of IrO₃ in the non-growth area is promoted.

10. The method of claim 7, wherein the growth area is an Al₂O₃ area, and the non-growth area is a SiO₂ area.
